(19) United States
(12) Patent Application Publication
(10) Pub. No.: US 2026/0136995 A1
(43) Pub. Date: May 14, 2026

(54) SEMICONDUCTOR PACKAGE

(71) Applicant: Samsung Electronics Co., Ltd., Suwon-si (KR)

(72) Inventors: HONGJIN KIM, Suwon-si (KR); KI-HONG JEONG, Suwon-si (KR)

(21) Appl. No.: 19/199,484

(22) Filed: May 6, 2025

(30) Foreign Application Priority Data
Nov. 13, 2024 (KR) 10-2024-0161253

(51) Int. Cl. H01L 25/07; H01L 23/00; H01L 23/31

(52) U.S. Cl. CPC H10W 90/00; H10W 72/884; H10W 72/886; H10W 74/111; H10W 90/24; H10W 90/732; H10W 90/734; H10W 90/754; H10W 90/762; H10W 90/764

(57) ABSTRACT

Disclosed is a semiconductor package comprising a package substrate that comprises a first pad and a second pad, a lower stack structure on the package substrate, an upper stack structure on the lower stack structure, and a wire that electrically connects the upper stack structure and the first pad to each other. The lower stack structure comprises a plurality of lower chips and a lower conductive structure that electrically connects the lower chips and the second pad to each other. The upper stack structure comprises a plurality of upper chips and an upper conductive structure that electrically connects the upper chips to each other.

### CROSS-REFERENCE TO RELATED APPLICATION

This application claims priority under 35 U.S.C § 119 to Korean Patent Application No. 10-2024-0161253 filed on Nov. 13, 2024 in the Korean Intellectual Property Office, the disclosure of which is hereby incorporated by reference in its entirety.

### BACKGROUND

The present inventive concepts relate to a semiconductor package, and more particularly, to a semiconductor package including a conductive structure.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies have been conducted to improve reliability and durability of semiconductor packages.

### SUMMARY

Some embodiments of the present inventive concepts provide a semiconductor package with improved electrical properties and increased reliability and a method of fabricating the same.

According to some embodiments of the present inventive concepts, a semiconductor package may comprise: a package substrate that comprises a first pad and a second pad; a lower stack structure on the package substrate; an upper stack structure on the lower stack structure; and a wire that electrically connects the upper stack structure and the first pad to each other. The lower stack structure may comprise: a plurality of lower chips; and a lower conductive structure that electrically connects the lower chips and the second pad to each other. The upper stack structure may comprise: a plurality of upper chips; and an upper conductive structure that electrically connects the upper chips to each other.

According to some embodiments of the present inventive concepts, a semiconductor package may comprise: a package substrate that comprises a first pad and a second pad; a lower stack structure on the package substrate; an upper stack structure on the lower stack structure; and a wire that electrically connects the upper stack structure and the first pad to each other. The lower stack structure may comprise: a first lower chip that comprises a first lower chip pad; a second lower chip that comprises a second lower chip pad, the second lower chip being at a level higher than a level of the first lower chip; and a lower conductive pattern that electrically connects the first lower chip pad, the second lower chip pad, and the second pad to each other. The upper stack structure may comprise: a first upper chip that comprises a first upper chip pad; a second upper chip that comprises a second upper chip pad, the second upper chip being at a level higher than a level of the first upper chip; and an upper conductive pattern that electrically connects the first upper chip pad and the second upper chip pad to each other.

According to some embodiments of the present inventive concepts, a semiconductor package may comprise: a package substrate that comprises a first pad and a second pad; a lower stack structure on the package substrate; an upper stack structure on the lower stack structure; a wire that electrically connects the upper stack structure and the first pad to each other; and a molding layer that encapsulates the lower stack structure, the upper stack structure, and the wire. The lower stack structure may comprise: a first lower chip that comprises a first lower chip pad; a first lower adhesion layer in contact with a bottom surface of the first lower chip; a second lower chip that comprises a second lower chip pad, the second lower chip being at a level higher than a level of the first lower chip; a second lower adhesion layer in contact with a bottom surface of the second lower chip; a first lower dielectric pattern in contact with a sidewall of the second lower chip; and a lower conductive structure in contact with the first lower chip pad, the second lower chip pad, the first lower dielectric pattern, and the second pad. The upper stack structure may comprises: a first upper chip that comprises a first upper chip pad; a first upper adhesion layer in contact with a bottom surface of the first upper chip; a second upper chip that comprise a second upper chip pad, the second upper chip being at a level higher than a level of the first upper chip; a second upper adhesion layer in contact with a bottom surface of the second upper chip; an upper dielectric pattern in contact with a sidewall of the second upper chip; and an upper conductive structure in contact with the first upper chip pad, the second upper chip pad, and the upper dielectric pattern. The first upper adhesion layer may be in contact with the lower conductive structure.

### BRIEF DESCRIPTION OF DRAWINGS

FIG. 1A illustrates a cross-sectional view showing a semiconductor package according to some embodiments.

FIG. 1B illustrates an enlarged view showing section Q1 of FIG. 1A.

FIG. 1C illustrates an enlarged view showing section Q2 of FIG. 1A.

FIGS. 2A, 2B, 2C, and 2D illustrate cross-sectional views showing a method of fabricating a semiconductor package according to some embodiments.

FIG. 3 illustrates a cross-sectional view showing a semiconductor package according to some embodiments.

FIG. 4 illustrates a cross-sectional view showing a semiconductor package according to some embodiments.

FIG. 5 illustrates a cross-sectional view showing a semiconductor package according to some embodiments.

FIG. 6 illustrates a cross-sectional view showing a semiconductor package according to some embodiments.

### DETAILED DESCRIPTION OF EMBODIMENTS

The following will describe in detail a semiconductor package and its fabrication method according to some embodiments of the present inventive concepts in conjunction with the accompanying drawings.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

As used herein, components described as being “electrically connected” are configured such that an electrical signal can be transferred from one component to the other (although such electrical signal may be attenuated in strength as it is transferred and may be selectively transferred).

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected,” “directly attached,” “directly joined,” or “directly coupled” to another element, or as “contacting” or “in contact with” another element (or using any form of the word “contact”), there are no intervening elements present at the point of contact.

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

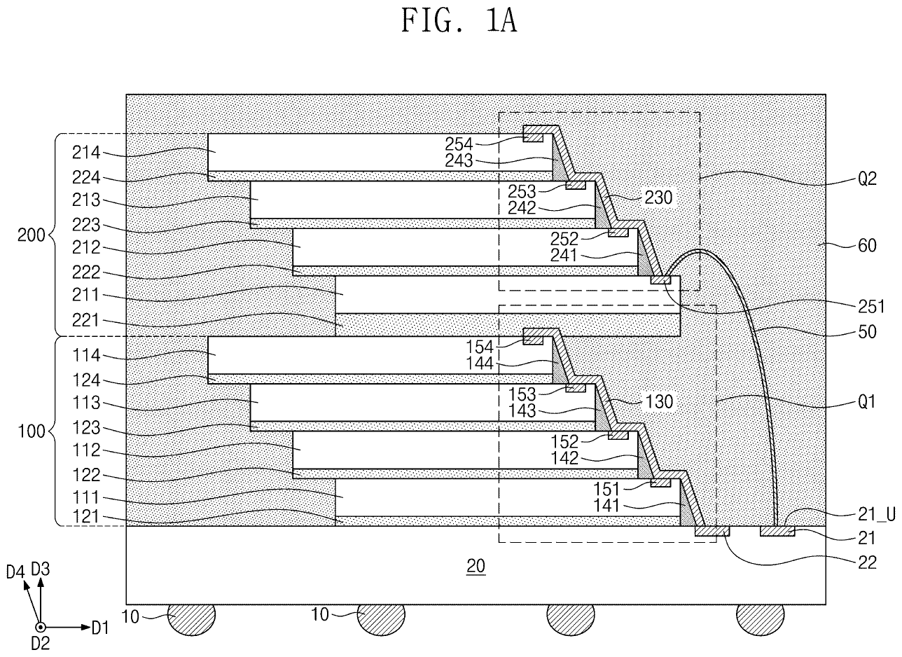

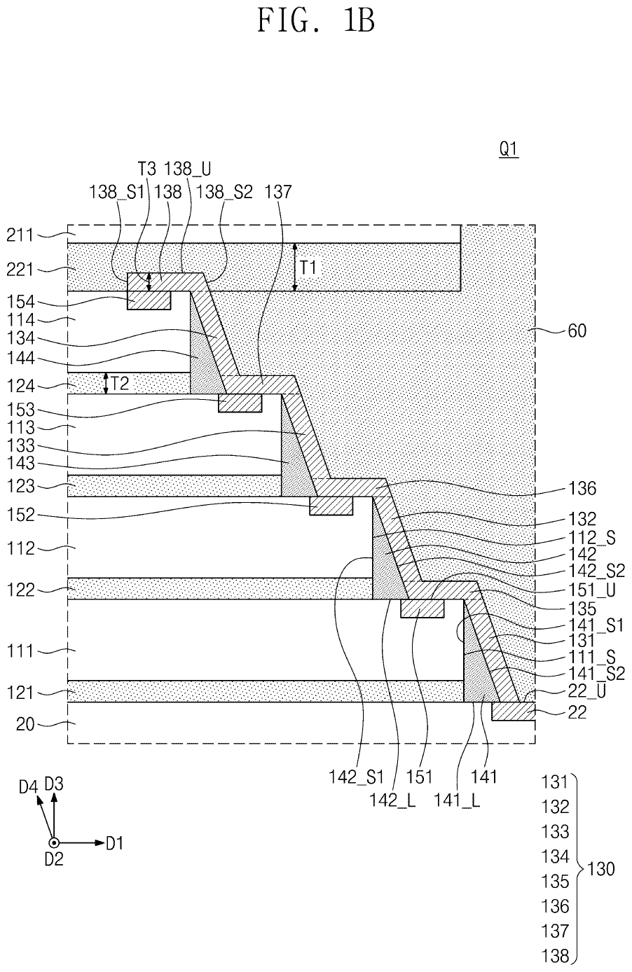

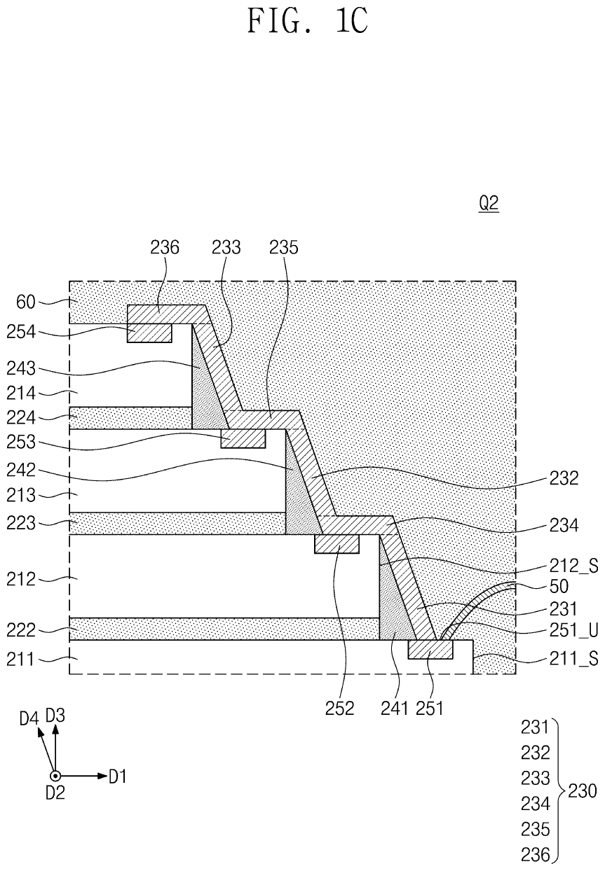

FIG. 1A illustrates a cross-sectional view showing a semiconductor package according to some embodiments. FIG. 1B illustrates an enlarged view showing section Q1 of FIG. 1A. FIG. 1C illustrates an enlarged view showing section Q2 of FIG. 1A.

Referring to FIG. 1A, a semiconductor package may include terminals 10, a package substrate 20, a lower stack structure 100, an upper stack structure 200, a wire 50, and a molding layer 60.

The package substrate 20 may have a plate shape elongated along a plane defined in a first direction D1 and a second direction D2. The first direction D1 and the second direction D2 may intersect each other. For example, the first direction D1 and the second direction D2 may be horizontal directions that are orthogonal to each other. For example, the package substrate 20 may extend in the first direction D1 and in the second direction D2.

In some embodiments, the package substrate 20 may be a printed circuit board. In some embodiments, the package substrate 20 may be a redistribution substrate. In some embodiments, the package substrate 20 may be an interposer including a semiconductor substrate.

The terminals 10 may be electrically connected to and/or contact the package substrate 20. The semiconductor package may be electrically connected through the terminals 10 to an external apparatus/device. The terminals 10 may include a conductive material.

The package substrate 20 may include a first pad 21 and a second pad 22. The first pad 21 and the second pad 22 may be exposed through a top surface of the package substrate 20. The first pad 21 and the second pad 22 may include a conductive material. For example, the first pad 21 and the second pad 22 may be formed of metal, e.g., a single element metal or a metal alloy. For example, the first pad 21 and the second pad 22 may include one or more of copper, gold, silver, copper, lead, tin, etc.

The lower stack structure 100 may be provided on the package substrate 20. The lower stack structure 100 may include lower chips 111, 112, 113, and 114, lower adhesion layers 121, 122, 123, and 124, a lower conductive structure 130, and lower dielectric patterns 141, 142, 143, and 144.

The lower chips 111, 112, 113, and 114 may include a first lower chip 111, a second lower chip 112, a third lower chip 113, and a fourth lower chip 114. Four lower chips 111, 112, 113, and 114 are illustrated in FIG. 1A and explained herein, but the number of the lower chips 111, 112, 113, and 114 is not limited thereto. In some embodiments, the number of the lower chips 111, 112, 113, and 114 may be three or less or five or more.

The first, second, third, and fourth lower chips 111, 112, 113, and 114 may overlap each other in a third direction D3. The third direction D3 may intersect the first direction D1 and the second direction D2. For example, the third direction D3 may be a vertical direction perpendicular to the first direction D1 and the second direction D2. The first, second, third, and fourth lower chips 111, 112, 113, and 114 may be sequentially arranged/stacked along the third direction D3.

The second lower chip 112 may be located at a higher level than the first lower chip 111. The third lower chip 113 may be located at a higher level than the second lower chip 112. The fourth lower chip 114 may be located at a higher level than the third lower chip 113. Among the first, second, third, and fourth lower chips 111, 112, 113, and 114, the first lower chip 111 may be disposed at a lowermost location. Among the first, second, third, and fourth lower chips 111, 112, 113, and 114, the fourth lower chip 114 may be disposed at an uppermost location.

Each of the lower chips 111, 112, 113, and 114 may be a semiconductor chip including a semiconductor device. Each of the lower chips 111, 112, 113, and 114 may be, for example, a memory chip including a memory device, a logic chip including a logic device, or an image sensor chip including an image sensor device.

The first lower chip 111 may include a first lower chip pad 151. The first lower chip pad 151 may be exposed through a top surface of the first lower chip 111. The second lower chip 112 may include a second lower chip pad 152. The second lower chip pad 152 may be exposed through a top surface of the second lower chip 112. The third lower chip 113 may include a third lower chip pad 153. The third lower chip pad 153 may be exposed through a top surface of the third lower chip 113. The fourth lower chip 114 may include a fourth lower chip pad 154. The fourth lower chip pad 154 may be exposed through a top surface of the fourth lower chip 114. The first, second, third, and fourth lower chip pads 151, 152, 153, and 154 may include a conductive material. For example, each of the first, second, third, and fourth lower chip pads 151, 152, 153, and 154 may be formed of metal e.g., a single element metal or a metal alloy. For example, the first, second, third, and fourth lower chip pads 151, 152, 153, and 154 may include one or more of copper, gold, silver, copper, lead, tin, etc.

The lower adhesion layers 121, 122, 123, and 124 may include a first lower adhesion layer 121, a second lower adhesion layer 122, a third lower adhesion layer 123, and a fourth lower adhesion layer 124. The first lower adhesion layer 121 may be disposed between the package substrate 20 and the first lower chip 111. The first lower adhesion layer 121 may be connected to the package substrate 20 and the first lower chip 111. The first lower adhesion layer 121 may be in contact with the top surface of the package substrate 20 and a bottom surface of the first lower chip 111.

The second lower adhesion layer 122 may be disposed between the first lower chip 111 and the second lower chip 112. The second lower adhesion layer 122 may be connected to the first lower chip 111 and the second lower chip 112. The second lower adhesion layer 122 may be in contact with the top surface of the first lower chip 111 and a bottom surface of the second lower chip 112.

The third lower adhesion layer 123 may be disposed between the second lower chip 112 and the third lower chip 113. The third lower adhesion layer 123 may be connected to the second lower chip 112 and the third lower chip 113. The third lower adhesion layer 123 may be in contact with the top surface of the second lower chip 112 and a bottom surface of the third lower chip 113.

The fourth lower adhesion layer 124 may be disposed between the third lower chip 113 and the fourth lower chip 114. The fourth lower adhesion layer 124 may be connected to the third lower chip 113 and the fourth lower chip 114. The fourth lower adhesion layer 124 may be in contact with the top surface of the third lower chip 113 and a bottom surface of the fourth lower chip 114.

The lower adhesion layers 121, 122, 123, and 124 may include an adhesive material. For example, each of the lower adhesion layers 121, 122, 123, and 124 may include a die attach film (DAF).

The lower conductive structure 130 may be provided on the lower chips 111, 112, 113, and 114. The lower conductive structure 130 may electrically connect the lower chips 111, 112, 113, and 114 to the second pad 22 of the package substrate 20. The lower conductive structure 120 may electrically connect the first, second, third, and fourth lower chip pads 151, 152, 153, and 154 to the second pad 22. The lower conductive structure 130 may be in contact with the first, second, third, and fourth lower chip pads 151, 152, 153, and 154 and the second pad 22. The lower conductive structure 130 may include a conductive material. For example, the lower conductive structure 130 may be a conductive pattern (e.g., a lower conductive pattern 130). For example, the lower conductive structure 130 may be a wire line or a wire. The lower conductive structure 130 may have a stepwise structure in a cross-sectional view as shown in FIG. 1A. The lower conductive structure 130 may have a straight line or bar shape in a plan view and/or in a side view shown in the first direction D1. For example, the lower conductive structure 130 may extend lengthwise in a plan view. In example embodiments, the lower conductive structure 130 may be formed of metal, e.g., a metal alloy. For example, the lower conductive structure 130 may include one or more of copper, aluminum, gold, silver, lead, tin, etc.

The lower dielectric patterns 141, 142, 143, and 144 may include a first lower dielectric pattern 141, a second lower dielectric pattern 142, a third lower dielectric pattern 143, and a fourth lower dielectric pattern 144. The first lower dielectric pattern 141 may be disposed between the lower conductive structure 130 and the first lower chip 111. The second lower dielectric pattern 142 may be disposed between the lower conductive structure 130 and the second lower chip 112. The third lower dielectric pattern 143 may be disposed between the lower conductive structure 130 and the third lower chip 113. The fourth lower dielectric pattern 144 may be disposed between the lower conductive structure 130 and the fourth lower chip 114. The lower dielectric patterns 141, 142, 143, and 144 may include a dielectric material.

The upper stack structure 200 may be provided on the lower stack structure 100. The lower stack structure 100 and the upper stack structure 200 may overlap each other in the third direction D3. The upper stack structure 200 may include upper chips 211, 212, 213, and 214, upper adhesion layers 221, 222, 223, and 224, an upper conductive structure 230, and dielectric patterns 241, 242, and 243.

The upper chips 211, 212, 213, and 214 may include a first upper chip 211, a second upper chip 212, a third upper chip 213, and a fourth upper chip 214. Four upper chips 211, 212, 213, and 214 are illustrated in FIG. 1A and explained herein, but the number of the upper chips 211, 212, 213, and 214 is not limited thereto. In some embodiments, the number of the upper chips 211, 212, 213, and 214 may be three or less or five or more.

The first, second, third, and fourth upper chips 211, 212, 213, and 214 may overlap each other in the third direction D3. The first, second, third, and fourth upper chips 211, 212, 213, and 214 may be sequentially arranged/stacked along the third direction D3.

The second upper chip 212 may be located at a higher level than the first upper chip 211. The third upper chip 213 may be located at a higher level than the second upper chip 212. The fourth upper chip 214 may be located at a higher level than the third upper chip 213. Among the upper chips 211, 212, 213, and 214, the first upper chip 211 may be disposed at a lowermost location. Among the upper chips 211, 212, 213, and 214, the fourth upper chip 214 may be disposed at an uppermost location. Each of the upper chips 211, 212, 213, and 214 may be a semiconductor chip including a semiconductor device.

The first upper chip 211 may include a first upper chip pad 251. The first upper chip pad 251 may be exposed through a top surface of the first upper chip 211. The second upper chip 212 may include a second upper chip pad 252. The second upper chip pad 252 may be exposed through a top surface of the second upper chip 212. The third upper chip 213 may include a third upper chip pad 253. The third upper chip pad 253 may be exposed through a top surface of the third upper chip 213. The fourth upper chip 214 may include a fourth upper chip pad 254. The fourth upper chip pad 254 may be exposed through a top surface of the fourth upper chip 214. The first, second, third, and fourth upper chip pads 251, 252, 253, and 254 may include a conductive material. For example, each of the first, second, third, and fourth upper chip pads 251, 252, 253, and 254 may be formed of metal, e.g., a single element metal or a metal alloy. For example, each of the first, second, third, and fourth upper chip pads 251, 252, 253, and 254 may include one or more of copper, aluminum, gold, silver, lead, tin, etc.

The upper adhesion layers 221, 222, 223, and 224 may include a first upper adhesion layer 221, a second upper adhesion layer 222, a third upper adhesion layer 223, and a fourth upper adhesion layer 224. The first upper adhesion layer 221 may be disposed between the fourth lower chip 114 and the first upper chip 211. The first upper adhesion layer 221 may be connected to the fourth lower chip 114 and the first upper chip 211. The first upper adhesion layer 221 may be in contact with the top surface of the fourth lower chip 114 and a bottom surface of the first upper chip 211.

The second upper adhesion layer 222 may be disposed between the first upper chip 211 and the second upper chip 212. The second upper adhesion layer 222 may be connected to the first upper chip 211 and the second upper chip 212. The second upper adhesion layer 222 may be in contact with the top surface of the first upper chip 211 and a bottom surface of the second upper chip 212.

The third upper adhesion layer 223 may be disposed between the second upper chip 212 and the third upper chip 213. The third upper adhesion layer 223 may be connected to the second upper chip 212 and the third upper chip 213. The third upper adhesion layer 223 may be in contact with the top surface of the second upper chip 212 and a bottom surface of the third upper chip 213.

The fourth upper adhesion layer 224 may be disposed between the third upper chip 213 and the fourth upper chip 214. The fourth upper adhesion layer 224 may be connected to the third upper chip 213 and the fourth upper chip 214. The fourth upper adhesion layer 224 may be in contact with the top surface of the third upper chip 213 and a bottom surface of the fourth upper chip 214.

The upper adhesion layers 221, 222, 223, and 224 may include an adhesive material. For example, each of the upper adhesion layers 221, 222, 223, and 224 may include a die attach film (DAF).

The upper conductive structure 230 may be provided on the upper chips 211, 212, 213, and 214. The upper conductive structure 230 may electrically connect the upper chips 211, 212, 213, and 214 to each other. The upper conductive structure 230 may be electrically connected to the first, second, third, and fourth upper chip pads 251, 252, 253, and 254. The upper conductive structure 230 may be in contact with the first, second, third, and fourth upper chip pads 251, 252, 253, and 254. The upper conductive structure 230 may include a conductive material. For example, the upper conductive structure 230 may be a conductive pattern (e.g., an upper conductive pattern 230). For example, the upper conductive structure 230 may be a wire line or a wire. The upper conductive structure 230 may have a stepwise structure in a cross-sectional view as shown in FIG. 1A. The upper conductive structure 230 may have a straight line or bar shape in a plan view and/or in a side view shown in the first direction D1. For example, the upper conductive structure 230 may extend lengthwise in a plan view. In example embodiments, the upper conductive structure 230 may be formed of metal, e.g., a metal alloy. For example, the upper conductive structure 230 may include one or more of copper, aluminum, gold, silver, etc.

The wire 50 may electrically connect the upper stack structure 200 to the first pad 21 of the package substrate 20. The wire 50 may be connected to the first upper chip pad 251 and the first pad 21. The wire 50 may electrically connect the first upper chip pad 251 to the first pad 21. The wire 50 may be in contact with the first upper chip pad 251 and the first pad 21. The wire 50 may be in contact with a top surface 21_U of the first pad 21. The wire 50 may include a conductive material. For example, the wire 50 may be a bonding wire. For example, the wire 50 may be formed of metal, e.g., a single element metal or a metal alloy. For example, the wire 50 may include gold, silver, copper, aluminum, lead, etc. The wire 50 may have a curved shape and surrounded by the molding layer 60 as shown in FIG. 1A.

The upper dielectric patterns 241, 242, and 243 may include a first upper dielectric pattern 241, a second upper dielectric pattern 242, and a third upper dielectric pattern 243. The first upper dielectric pattern 241 may be disposed between the upper conductive structure 230 and the second upper chip 212. The second upper dielectric pattern 242 may be disposed between the upper conductive structure 230 and the third upper chip 213. The third upper dielectric pattern 243 may be disposed between the upper conductive structure 230 and the fourth upper chip 214. The upper dielectric patterns 241, 242, and 243 may include a dielectric material.

The molding layer 60 may be provided to encapsulate the lower stack structure 100, the upper stack structure 200, and the wire 50. The molding layer 60 may be provided on the package substrate 20. For example, the molding layer 60 may contact the top surface of the package substrate 20. The molding layer 60 may include a dielectric material. For example, the molding layer may include an epoxy molding compound (EMC).

The second pad 22 may be disposed between the first pad 21 and the lower stack structure 100. For example, the second pad 22 may be disposed closer than the first pad 21 to the lower stack structure 100. The first pad 21 may be spaced apart in the first direction D1 from the lower stack structure 100. The first pad 21 may be spaced apart in the first direction D1 from the second pad 22. A distance in the first direction D1 between the first pad 21 and the second pad 22 may be less than a width in the first direction D1 of the first lower chip 111.

Referring to FIG. 1B, the lower conductive structure 130 may include a first connection part 131 in contact with the second pad 22 and the first lower dielectric pattern 141, a first contact part 135 in contact with the first lower chip pad 151, a second connection part 132 in contact with the second lower dielectric pattern 142, a second contact part 136 in contact with the second lower chip pad 152, a third connection part 133 in contact with the third lower dielectric pattern 143, a third contact part 137 in contact with the third lower chip pad 153, a fourth connection part 134 in contact with the fourth lower dielectric pattern 144, and a fourth contact part 138 in contact with the fourth lower chip pad 154. Each of connection parts 131, 132, 133 and 134, and contact parts 135, 136, 137 and 138 of the lower conductive structure 130 may be a conductor pattern, e.g., a connection pattern (131, 132, 133, or 134) or a contact pattern (135, 136, 137, or 138).

The first contact part 135 may be a portion located at a higher level than the first lower chip 111. The second contact part 136 may be a portion located at a higher level than the second lower chip 112. The third contact part 137 may be a portion located at a higher level than the third lower chip 113. The fourth contact part 138 may be a portion located at a higher level than the fourth lower chip 114.

The second connection part 132 may electrically connect and be integrally formed (e.g., as one body without a boundary) with the first and second contact parts 135 and 135 to each other. The third connection part 133 may electrically connect and be integrally formed (e.g., as one body without a boundary) with the second and third contact parts 136 and 137 to each other. The fourth connection part 134 may electrically connect and be integrally formed (e.g., as one body without a boundary) with the third and fourth contact parts 137 and 138 to each other.

The first upper adhesion layer 221 may surround the fourth contact part 138. A top surface 138_U, a first sidewall 138_S1, and a second sidewall 138_S2 of the fourth contact part 138 may be in contact with the first upper adhesion layer 221. The first sidewall 138_S1 and the second sidewall 138_S2 of the fourth contact part 138 may stand opposite to each other. The first sidewall 138_S1 of the fourth contact part 138 may be parallel to the second direction D2 and the third direction D3. The second sidewall 138_S2 of the fourth contact part 138 may be parallel to the second direction D2 and a fourth direction D4. The fourth direction D4 may intersect the first, second, and third directions D1, D2, and D3. The second sidewall 138_S2 of the fourth contact part 138 may be inclined with respect to the top surface 138_U of the fourth contact part 138.

A thickness T3 in the third direction D3 of the fourth contact part 138 may be less than a thickness T1 in the third direction D3 of the first upper adhesion layer 221.

The first connection part 131 may be in contact with a top surface 22_U of the second pad 22.

A first sidewall 141_S1 of the first lower dielectric pattern 141 may be in contact with a sidewall 111_S of the first lower chip 111 and a sidewall of the first lower adhesion layer 121. A second sidewall 141_S2 of the first lower dielectric pattern 141 may be in contact with the first connection part 131. The first sidewall 141_S1 and the second sidewall 141_S2 of the first lower dielectric pattern 141 may stand opposite to each other, e.g., at an angle. The first sidewall 141_S1 of the first lower dielectric pattern 141 may be parallel to the second direction D2 and the third direction D3. The second sidewall 141_S2 of the first lower dielectric pattern 141 may be parallel to the second direction D2 and the fourth direction D4. A bottom surface 141_L of the first lower dielectric pattern 141 may be in contact with the top surface 22_U of the second pad 22.

A first sidewall 142_S1 of the second lower dielectric pattern 142 may be in contact with a sidewall 112_S of the second lower chip 112 and a sidewall of the second lower adhesion layer 122. A second sidewall 142_S2 of the second lower dielectric pattern 142 may be in contact with the second connection part 132 and the first contact part 135. The first sidewall 142_S1 and the second sidewall 141_S2 of the second lower dielectric pattern 142 may stand opposite to each other. The first sidewall 142_S1 of the second lower dielectric pattern 142 may be parallel to the second direction D2 and the third direction D3. The second sidewall 142_S2 of the second lower dielectric pattern 142 may be parallel to the second direction D2 and the fourth direction D4. A bottom surface 142_L of the second lower dielectric pattern 142 may be in contact with a top surface 151_U of the first lower chip pad 151.

Referring to FIG. 1C, the upper conductive structure 230 may include a first connection part 231 in contact with the first upper chip pad 251 and the first upper dielectric pattern 241, a first contact part 234 in contact with the second upper chip pad 252, a second connection part 232 in contact with the second upper dielectric pattern 242, a second contact part 235 in contact with the third upper chip pad 253, a third connection part 233 in contact with the third upper dielectric pattern 243, and a third contact part 236 in contact with the fourth upper chip pad 254. Each of connection parts 231, 232, and 233, and contact parts 234, 235, and 236 of the upper conductive structure 230 may be a conductor pattern, e.g., a connection pattern (231, 232, or 233) or a contact pattern (234, 235, or 236).

The first contact part 234 may be a portion located at a higher level than the first upper chip 211. The second contact part 235 may be a portion located at a higher level than the second upper chip 212. The third contact part 236 may be a portion located at a higher level than the third upper chip 213.

The second connection part 232 may electrically connect and be integrally formed (e.g., as one body without a boundary) with the first and second contact parts 234 and 235 to each other. The third connection part 233 may electrically connect and be integrally formed (e.g., as one body without a boundary) with the second and third contact parts 235 and 236 to each other. The first connection part 231 may be in contact with a top surface 251_U of the first upper chip pad 251.

The first upper dielectric pattern 241 may be in contact with a sidewall 212_S of the second upper chip 212 and a sidewall of the second upper adhesion layer 222. The first upper dielectric pattern 241 may be in contact with the top surface 251_U of the first upper chip pad 251. The wire 50 may be in contact with the top surface 251_U of the first upper chip pad 251.

Referring to FIGS. 1A, 1B, and 1C, the thickness T1 in the third direction D3 of the first upper adhesion layer 221 may be greater than thicknesses in the third direction D3 of the first, second, third, and fourth lower adhesion layers 121, 122, 123, and 124 and thicknesses in the third direction D3 of the second, third, and fourth upper adhesion layers 222, 223, and 224. For example, the thickness T1 in the third direction D3 of the first upper adhesion layer 221 may be greater than a thickness T2 in the third direction D3 of the fourth lower adhesion layer 124. In some embodiments, the first, second, third, and fourth lower adhesion layers 121, 122, 123, and 124 and the second, third, and fourth upper adhesion layers 222, 223, and 224 may have the same thickness in the third direction D3.

In some embodiments, the first lower chip 111 may completely overlap in the third direction D3 with the first upper chip 211. For example, the first lower chip 111 may not have a portion that does not overlap in the third direction D3 with the first upper chip 211. In some embodiments, the second lower chip 112 may completely overlap in the third direction D3 with the second upper chip 212. In some embodiments, the third lower chip 113 may completely overlap in the third direction D3 with the third upper chip 213. In some embodiments, the fourth lower chip 114 may completely overlap in the third direction D3 with the fourth upper chip 214.

In some embodiments, the sidewall 111_S of the first lower chip 111 may overlap in the third direction D3 with the sidewall 211_S of the first upper chip 211. In some embodiments, the sidewall 112_S of the second lower chip 112 may overlap in the third direction D3 with the sidewall 212_S of the second upper chip 212.

The first, second, third, and fourth lower chips 111, 112, 113, and 114 may have their sidewalls that are spaced apart from each other in the first direction D1. The first, second, third, and fourth upper chips 211, 212, 213, and 214 may have their sidewalls that are spaced apart from each other in the first direction D1. In some embodiments, a distance in the first direction D1 between the sidewalls 111_S and 112_S of the first and second lower chips 111 and 112 may be the same as a distance in the first direction D1 between the sidewalls 211_S and 212_S of the first and second upper chips 211 and 212.

In some embodiments, a width in the first direction D1 of the lower chips 111, 112, 113, and 114 may be the same as a width in the first direction D1 of the upper chips 211, 212, 213, and 214. For example, widths of the lower chips 111, 112, 113, and 114 and the upper chips 211, 212, 213, and 214 in the first direction D1 may be the same as each other.

The first lower chip pad 151 and the first upper chip pad 251 may overlap each other in the third direction D3. The second lower chip pad 152 and the second upper chip pad 252 may overlap each other in the third direction D3. The third lower chip pad 153 and the third upper chip pad 253 may overlap each other in the third direction D3. The fourth lower chip pad 154 and the fourth upper chip pad 254 may overlap each other in the third direction D3. The lower conductive structure 130 may overlap in the third direction D3 with the upper conductive structure 230.

The second lower dielectric pattern 142 may overlap in the third direction D3 with the first upper dielectric pattern 241. The third lower dielectric pattern 143 may overlap in the third direction D3 with the second upper dielectric pattern 242. The fourth lower dielectric pattern 144 may overlap in the third direction D3 with the third upper dielectric pattern 243.

In the semiconductor package according to some embodiments, the lower chips 111, 112, 113, and 114 may be electrically connected through the lower conductive structure 130 to the package substrate 20. Therefore, it may not be needed to form a wire loop above the fourth lower chip 114, and thus a reduced distance may be provided between the fourth lower chip 114 and the first upper chip 211.

In the semiconductor package according to some embodiments, the upper chips 211, 212, 213, and 214 may be electrically connected through the upper conductive structure 230 and the wire 50 to the package substrate 20. Therefore, it may not be needed to form a wire loop above the fourth upper chip 214, and thus the molding layer 60 may have a reduced height.

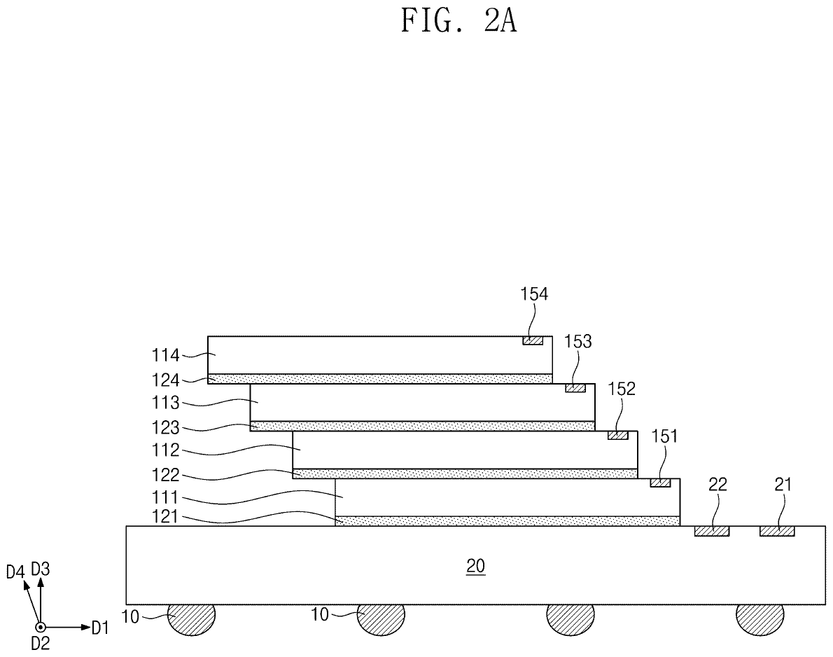

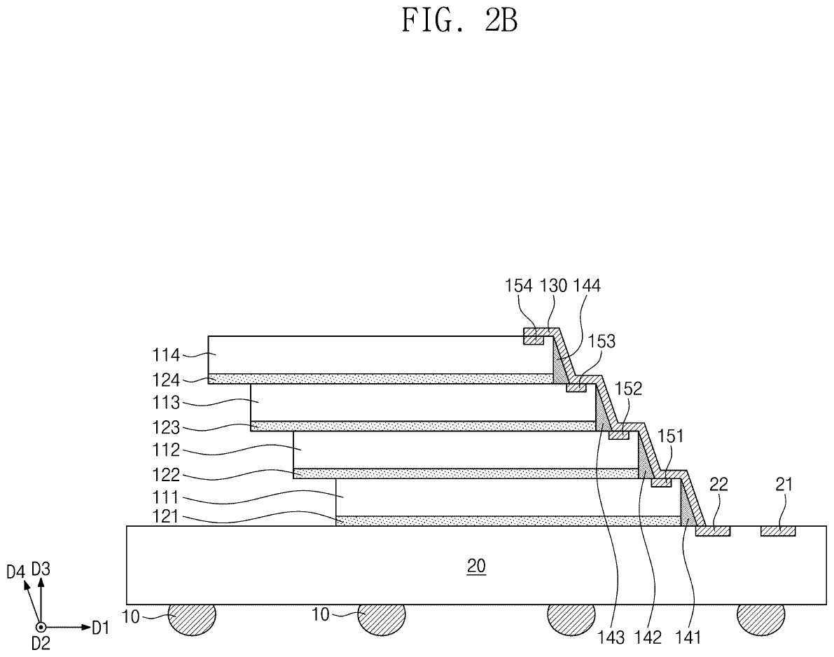

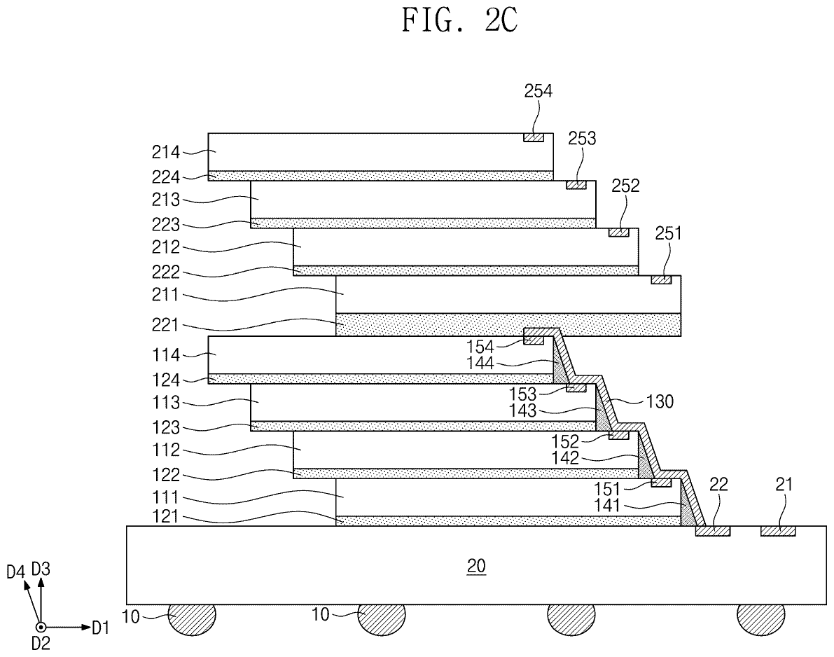

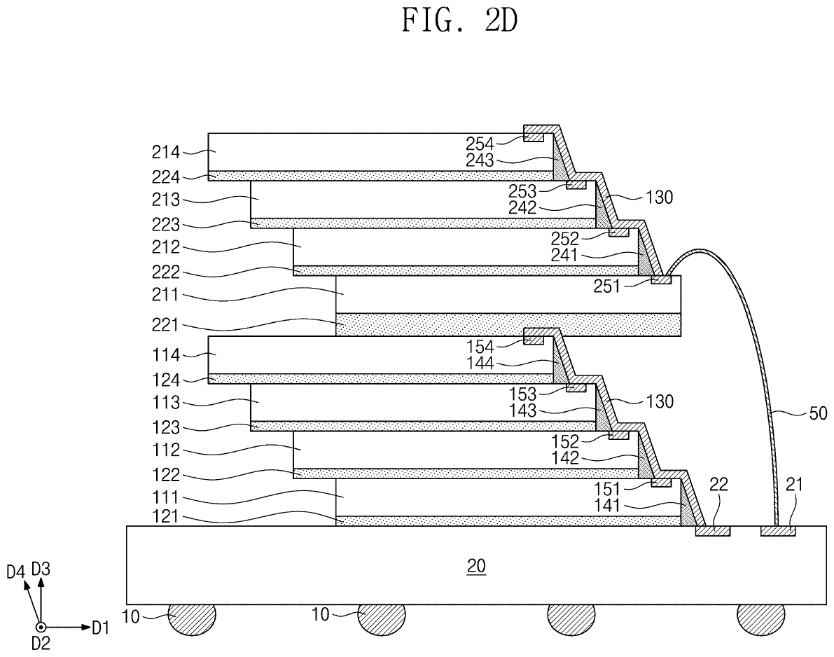

FIGS. 2A, 2B, 2C, and 2D illustrate cross-sectional views showing a method of fabricating a semiconductor package according to some embodiments.

Referring to FIG. 2A, terminals 10 may be formed on a package substrate 20. For example, the terminals 10 may be formed on the package substrate 20 before the lower and upper stack structures 100 and 200 are formed on the package substrate. In certain embodiments, the terminals 10 may be formed on the package substrate 20 after the lower and upper stack structures 100 and 200 are formed on the package substrate. Lower adhesion layers 121, 122, 123, and 124 and lower chips 111, 112, 113, and 114 may be formed on the package substrate 20. For example, the lower adhesion layers 121, 122, 123, and 124 may be respectively formed/attached on the lower chips 111, 112, 113, and 114, and then attached to the package substrate 20 in sequence. In certain embodiments, the lower adhesion layers 121, 122, 123, and 124 may be formed/attached on the lower chips 111, 112, 113, and 114 respectively and attached/stacked together in sequence, and then the stacked structure may be attached on the package substrate 20.

Referring to FIG. 2B, lower dielectric patterns 141, 142, 143, and 144 may be formed on the lower chips 111, 112, 113, and 114. For example, the lower dielectric patterns 141, 142, 143, and 144 may be formed by a printing process, a photolithography process or a blanket etch process. For example, the lower dielectric patterns 141, 142, 143, and 144 may be formed of a printing material or a photoresist material. In some embodiments, the lower dielectric patterns 141, 142, 143, and 144 may be formed of a dielectric material other than a printing material and a photoresist material. In this case, after a dielectric layer is formed on the lower stack structure 100, the dielectric layer may be patterned by a blanket etch or by a photolithography process.

A lower conductive structure 130 may be formed on the lower stack structure 100 and the package substrate 20. In some embodiments, the formation of the lower conductive structure 130 may include performing a direct printing process to form the lower conductive structure 130.

Referring to FIG. 2C, upper adhesion layers 221, 222, 223, and 224 and upper chips 211, 212, 213, and 214 may be formed on a fourth lower chip 114. The formation of the upper adhesion layers 221, 222, 223, and 224 and the upper chips 211, 212, 213, and 214 may include forming a first upper adhesion layer 221 on a first upper chip 211, and bonding the first upper adhesion layer 221 to the fourth lower chip 114 and a fourth contact part (see 138 of FIG. 1B) of the lower conductive structure 130. For example, after bonding the upper chips 211, 212, 213, and 214 using the upper adhesion layers 222, 223, and 224 together to form the upper stack structure 200, the upper stack structure 200 may be attached to the lower stack structure 100 using the first upper adhesion layer 221. In certain embodiments, the upper chips 211, 212, 213, and 214 may be sequentially attached on the lower stack structure 100.

Referring to FIG. 2D, upper dielectric patterns 241, 242, and 243 may be formed on the upper chips 211, 212, 213, and 214. For example, the upper dielectric patterns 241, 242, and 243 may be formed by the same way as one of the processes forming the lower dielectric patterns 141, 142, 143, and 144 described above.

An upper conductive structure 230 may be formed on the upper chips 211, 212, 213, and 214. In some embodiments, the formation of the upper conductive structure 230 may include performing a direct printing process to form the upper conductive structure 230.

A wire 50 may be formed to electrically connect a first upper chip pad 251 and a first pad 21 to each other.

Referring to FIG. 1A, a molding layer 60 may be formed on the lower stack structure 100, the upper stack structure 200, and the package substrate 20.

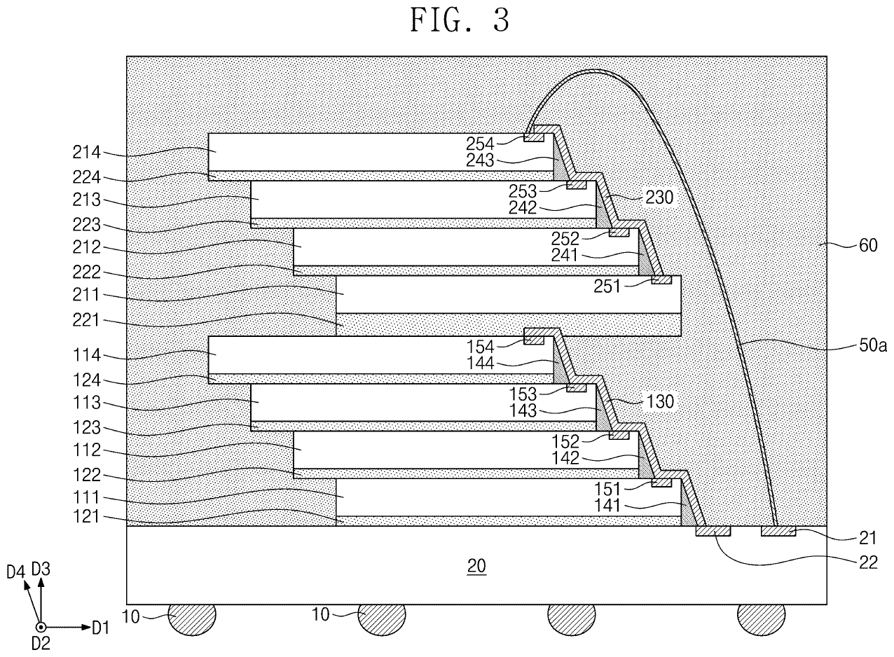

FIG. 3 illustrates a cross-sectional view showing a semiconductor package according to some embodiments. Except that discussed below, the semiconductor package according to the embodiments illustrated in FIG. 3 may be the same as or similar to the semiconductor package according to embodiments described with reference to FIGS. 1A to 1C.

Referring to FIG. 3, a wire 50a may be connected to the first pad 21 and the fourth upper chip pad 254 of the fourth upper chip 214. The wire 50a may be in contact with a top surface of the first pad 21 and a top surface of the fourth upper chip pad 254 of the fourth upper chip 214.

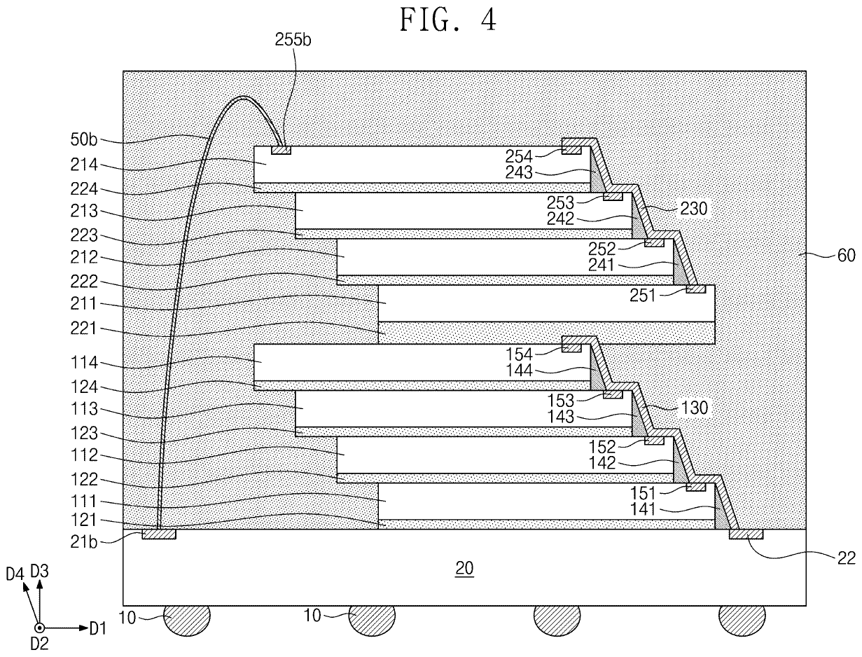

FIG. 4 illustrates a cross-sectional view showing a semiconductor package according to some embodiments. Except that discussed below, the semiconductor package according to the embodiments illustrated in FIG. 4 may be the same as or similar to the semiconductor package according to embodiments described with respect to FIGS. 1A to 1C.

Referring to FIG. 4, a first pad 21b and the second pad 22 may be spaced apart in the first direction D1 from each other across the lower chips 111, 112, 113, and 114 and the upper chips 211, 212, 213, and 214. The first pad 21b may be disposed on one side of the lower chips 111, 112, 113, and 114 and the upper chips 211, 212, 213, and 214, and the second pad 22 may be disposed on another side of the lower chips 111, 112, 113, and 114 and the upper chips 211, 212, 213, and 214. For example, the first pad 21b and the second pad 22 may be disposed at opposite sides of the lower stack structure 100, e.g., in the first direction D1.

The fourth upper chip 214 may further include a fifth upper chip pad 255b. The fifth upper chip pad 255b may be spaced apart from the upper conductive structure 230. A wire 50b may be electrically connected to the fifth upper chip pad 255b and the first pad 21b. The wire 50b may be in contact with the fifth upper chip pad 255b and the first pad 21b.

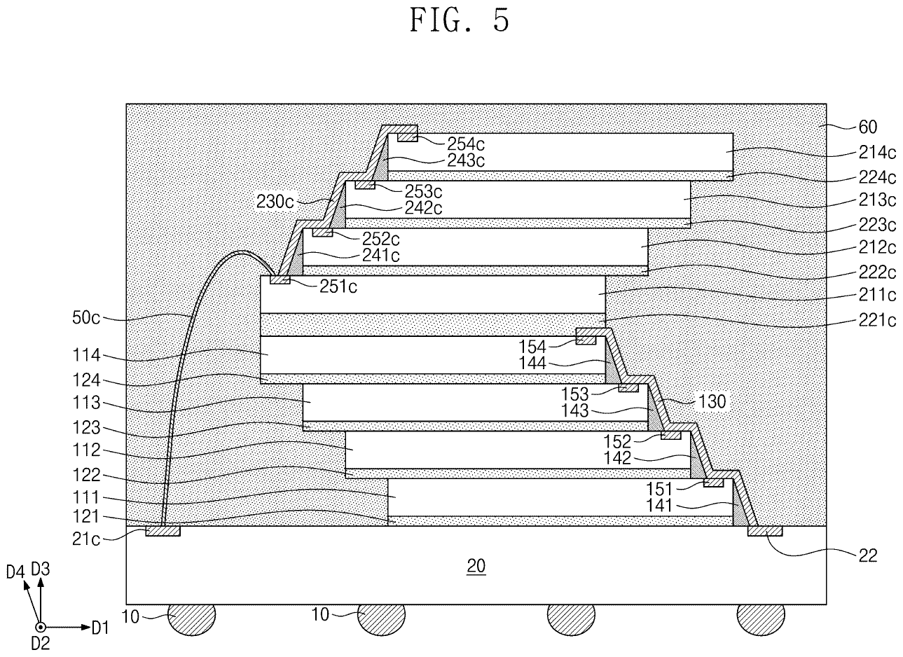

FIG. 5 illustrates a cross-sectional view showing a semiconductor package according to some embodiments. Except that discussed below, the semiconductor package according to the embodiments illustrated in FIG. 5 may be the same as or similar to the semiconductor package according to embodiments described with reference to FIGS. 1A to 1C.

Referring to FIG. 5, the fourth lower chip 114, a first upper adhesion layer 221c, and a first upper chip 211c may completely overlap each other in the third direction D3. The fourth lower chip 114, the first upper adhesion layer 221c, and the first upper chip 211c may have their sidewalls coplanar with each other.

A second upper chip 212c may completely overlap in the third direction D3 with the third lower chip 113. A third upper chip 213c may completely overlap in the third direction D3 with the second lower chip 112. A fourth upper chip 214c may completely overlap in the third direction D3 with the first lower chip 111.

A second upper adhesion layer 222c may completely overlap in the third direction D3 with the third lower adhesion layer 123. A third upper adhesion layer 223c may completely overlap in the third direction D3 with the second lower adhesion layer 122. A fourth upper adhesion layer 224c may completely overlap in the third direction D3 with the first lower adhesion layer 121.

The lower conductive structure 130 may not overlap in the third direction D3 with an upper conductive structure 230c. The lower chip pads 151, 152, 153, and 154 may not overlap in the third direction D3 with upper chip pads 251c, 252c, 253c, and 254c. The lower dielectric patterns 141, 142, 143, and 144 may not overlap in the third direction D3 with upper dielectric patterns 241c, 242c, and 243c.

A first pad 21c and the second pad 22 may be spaced apart in the first direction D1 from each other across the lower chips 111, 112, 113, and 114 and the upper chips 211c, 212c, 213c, and 214c. For example, the first pad 21c and the second pad 22 may be disposed at opposite sides of the lower stack structure 100, e.g., in the first direction D1. A wire 50c may electrically connect a first upper chip pad 251c and the first pad 21c to each other. The wire 50c may be in contact with the first upper chip pad 251c and the first pad 21c.

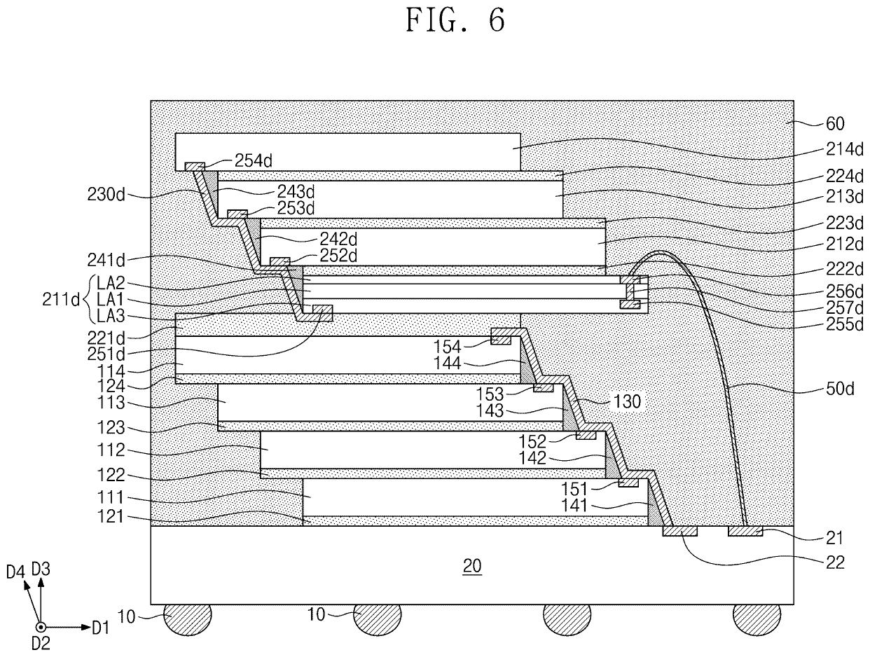

FIG. 6 illustrates a cross-sectional view showing a semiconductor package according to some embodiments. Except that discussed below, the semiconductor package according to the embodiments illustrated in FIG. 6 may be the same as or similar to the semiconductor package according to embodiments described with respect to FIGS. 1A to 1C.

Referring to FIG. 6, a first upper chip pad 251d may be exposed through a bottom surface of a first upper chip 211d. A second upper chip pad 252d may be exposed through a bottom surface of a second upper chip 212d. A third upper chip pad 253d may be exposed through a bottom surface of a third upper chip 213d. A fourth upper chip pad 254d may be exposed through a bottom surface of a fourth upper chip 214d.

An upper conductive structure 230d may electrically connect the first, second, third, and fourth upper chip pads 251d, 252d, 253d, and 254d to each other. The upper conductive structure 230d may be in contact with bottom surfaces of the first, second, third, and fourth upper chip pads 251d, 252d, 253d, and 254d.

A first upper adhesion layer 221d may surround a contact part of the lower conductive structure 130, and the contact part is in contact with the fourth lower chip pad 154. The first upper adhesion layer 221d may also surround a contact part of the upper conductive structure 230d, and the contact part is in contact with the first upper chip pad 251d. The first upper adhesion layer 221d may be in contact with the contact part of the lower conductive structure 130 and the contact part of the upper conductive structure 230d.

A second upper adhesion layer 222d may be disposed between the first and second upper chips 211d and 212d. The second upper adhesion layer 222d may partially expose a top surface of the first upper chip 211d. A third upper adhesion layer 223d may be disposed between the second and third upper chips 212d and 213d. A fourth upper adhesion layer 224d may be disposed between the third and fourth upper chips 213d and 214d.

A first upper dielectric pattern 241d may be in contact with a sidewall of the first upper chip 211d, a bottom surface of the second upper chip 212d, and the upper conductive structure 230d. A second upper dielectric pattern 242d may be in contact with a sidewall of the second upper chip 212d, a bottom surface of the third upper chip 213d, and the upper conductive structure 230d. A third upper dielectric pattern 243d may be in contact with a sidewall of the third upper chip 213d, a bottom surface of the fourth upper chip 214d, and the upper conductive structure 230d.

The first upper chip 211d may include a substrate LA1, and may also include a first dielectric structure LA2 and a second dielectric structure LA3 that are spaced apart in the third direction D3 from each other across the substrate LA1. For example, the first dielectric structure LA2 and the second dielectric structure LA3 may be disposed on opposite surfaces of the substrate LA1 in a vertical direction. The first dielectric structure LA2 may be in contact with a top surface of the substrate LA1. The second dielectric structure LA3 may be in contact with a bottom surface of the substrate LA1.

The substrate LA1 may be a semiconductor substrate. For example, the substrate LA1 may include silicon, germanium, or silicon-germanium. The first and second dielectric structures LA2 and LA3 may include a dielectric material. In some embodiments, each of the first and second dielectric structures LA2 and LA3 may be a multiple layer structure including a plurality of dielectric layers, e.g., stacked in a vertical direction.

The first upper chip 211d may include a semiconductor device on the bottom surface of the substrate LA1. For example, the bottom surface of the substrate LA1 may be an active surface or a circuit surface of the first upper chip 211D. The semiconductor device may be disposed between the substrate LA1 and the second dielectric structure LA3.

The first upper chip 211d may include a fifth upper chip pad 255d surrounded by the second dielectric structure LA3, a sixth upper chip pad 256d surrounded by the first dielectric structure LA2, and a through via 257d that penetrates in the third direction D3 through the substrate LA1. The substrate LA1 may be disposed between the fifth upper chip pad 255d and the sixth upper chip pad 256d.

The fifth upper chip pad 255d and the sixth upper chip pad 256d may be electrically connected through the through via 257d. The fifth upper chip pad 255 d and the sixth upper chip pad 256 d may be in contact with the through via 257d. The sixth upper chip pad 256d may be exposed through a top surface of the first upper chip 211d. The sixth upper chip pad 256d may be exposed through a top surface of the first dielectric structure LA2. A wire 50d may be in contact with a top surface of the sixth upper chip pad 256d.

A semiconductor package according to some embodiments of the present inventive concepts may include a conductive structure and a wire, thereby having a minimized size.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Although the present invention has been described in connection with the embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is

1. A semiconductor package, comprising:
a package substrate that comprises a first pad and a second pad;
a lower stack structure on the package substrate;
an upper stack structure on the lower stack structure; and
a wire that electrically connects the upper stack structure and the first pad to each other,
wherein the lower stack structure comprises:
a plurality of lower chips; and
a lower conductive structure that electrically connects the lower chips and the second pad to each other,
wherein the upper stack structure comprises:
a plurality of upper chips; and
an upper conductive structure that electrically connects the upper chips to each other.

2. The semiconductor package of claim 1, wherein the second pad is between the first pad and the lower stack structure.

3. The semiconductor package of claim 1, wherein
the lower stack structure and the first pad are spaced apart from each other in a first direction, and
a width in the first direction of the lower chips is the same as a width in the first direction of the upper chips.

4. The semiconductor package of claim 1,
wherein the lower chips comprise:
a first lower chip at a lowermost location among the lower chips; and
a second lower chip at a level higher than a level of the first lower chip, and
wherein the upper chips comprise:
a first upper chip at a lowermost location among the upper chips; and
a second upper chip at a level higher than a level of the first upper chip.

5. The semiconductor package of claim 4,
wherein the lower stack structure comprises:
a first lower dielectric pattern between the lower conductive structure and the first lower chip; and
a second lower dielectric pattern between the lower conductive structure and the second lower chip, and
wherein the upper stack structure comprises an upper dielectric pattern between the upper conductive structure and the second upper chip.

6. The semiconductor package of claim 4,
wherein the lower stack structure comprises:
a first lower adhesion layer in contact with a bottom surface of the first lower chip; and
a second lower adhesion layer in contact with a bottom surface of the second lower chip,
wherein the upper stack structure comprises:
a first upper adhesion layer in contact with a bottom surface of the first upper chip; and
a second upper adhesion layer in contact with a bottom surface of the second upper chip,
wherein a thickness of the first upper adhesion layer is greater than a thickness of the first lower adhesion layer, a thickness of the second lower adhesion layer, and a thickness of the second upper adhesion layer.

7. The semiconductor package of claim 4, wherein a sidewall of the first lower chip overlaps a sidewall of the first upper chip, and a sidewall of the second lower chip overlaps a sidewall of the second upper chip.

8. A semiconductor package, comprising:
a package substrate that comprises a first pad and a second pad;
a lower stack structure on the package substrate;
an upper stack structure on the lower stack structure; and
a wire that electrically connects the upper stack structure and the first pad to each other,
wherein the lower stack structure comprises:
a first lower chip that comprises a first lower chip pad;
a second lower chip that comprises a second lower chip pad, the second lower chip being at a level higher than a level of the first lower chip; and
a lower conductive pattern that electrically connects the first lower chip pad, the second lower chip pad, and the second pad to each other,
wherein the upper stack structure comprises:
a first upper chip that comprises a first upper chip pad;
a second upper chip that comprises a second upper chip pad, the second upper chip being at a level higher than a level of the first upper chip; and
an upper conductive pattern that electrically connects the first upper chip pad and the second upper chip pad to each other.

9. The semiconductor package of claim 8, wherein the first upper chip comprises:
a substrate;
a through via that penetrates the substrate; and
a third upper chip pad in contact with the through via,
wherein the substrate is between the first upper chip pad and the third upper chip pad, and
wherein the third upper chip pad is in contact with the wire.

10. The semiconductor package of claim 9, wherein the first upper chip comprises:
a first dielectric structure that surrounds the first upper chip pad; and
a second dielectric structure that surrounds the third upper chip pad,
wherein the substrate is between the first dielectric structure and the second dielectric structure.

11. The semiconductor package of claim 9, wherein
a bottom surface of the first upper chip pad and a bottom surface of the second upper chip pad are in contact with the upper conductive pattern, and
a top surface of the third upper chip pad is in contact with the wire.

12. The semiconductor package of claim 8, wherein the lower conductive pattern comprises:
a first connection part in contact with the second pad;
a first contact part in contact with the first lower chip pad;
a second contact part in contact with the second lower chip pad; and
a second connection part that electrically connects the first contact part and the second contact part to each other,
wherein the upper stack structure further comprises an upper adhesion layer in contact with a bottom surface of the first upper chip, and
wherein a thickness of the upper adhesion layer is greater than a thickness of the second contact part.

13. The semiconductor package of claim 12, wherein the upper adhesion layer surrounds the second contact part.

14. The semiconductor package of claim 12, wherein the second contact part has a first sidewall, a second sidewall, and a top surface that are in contact with the upper adhesion layer,
wherein the first sidewall and the second sidewall of the second contact part stand opposite to each other,
wherein the first sidewall of the second contact part is parallel to a first direction and a second direction crossed to the first direction, and
wherein the second sidewall of the second contact part is parallel to the first direction and a third direction that is crossed to the first direction and the second direction.

15. The semiconductor package of claim 8, wherein the wire is in contact with the second upper chip pad.

16. The semiconductor package of claim 8, wherein the lower conductive pattern and the upper conductive pattern overlap each other in a vertical direction.

17. A semiconductor package, comprising:
a package substrate that comprises a first pad and a second pad;
a lower stack structure on the package substrate;
an upper stack structure on the lower stack structure;
a wire that electrically connects the upper stack structure and the first pad to each other; and
a molding layer that encapsulates the lower stack structure, the upper stack structure, and the wire,
wherein the lower stack structure comprises:
a first lower chip that comprises a first lower chip pad;
a first lower adhesion layer in contact with a bottom surface of the first lower chip;
a second lower chip that comprises a second lower chip pad, the second lower chip being at a level higher than a level of the first lower chip;
a second lower adhesion layer in contact with a bottom surface of the second lower chip;
a first lower dielectric pattern in contact with a sidewall of the second lower chip; and
a lower conductive structure in contact with the first lower chip pad, the second lower chip pad, the first lower dielectric pattern, and the second pad,
wherein the upper stack structure comprises:
a first upper chip that comprises a first upper chip pad;
a first upper adhesion layer in contact with a bottom surface of the first upper chip;
a second upper chip that comprise a second upper chip pad, the second upper chip being at a level higher than a level of the first upper chip;
a second upper adhesion layer in contact with a bottom surface of the second upper chip;
an upper dielectric pattern in contact with a sidewall of the second upper chip; and
an upper conductive structure in contact with the first upper chip pad, the second upper chip pad, and the upper dielectric pattern,
wherein the first upper adhesion layer is in contact with the lower conductive structure.

18. The semiconductor package of claim 17, wherein
the first lower chip pad and the first upper chip pad overlap each other in a vertical direction, and
the second lower chip pad and the second upper chip pad overlap each other in the vertical direction.

19. The semiconductor package of claim 17, wherein the lower stack structure further comprises as second lower dielectric pattern in contact with a sidewall of the first lower chip,
wherein the second lower dielectric pattern is in contact with a top surface of the second pad.

20. The semiconductor package of claim 17, wherein a distance in a first direction between the first pad and the second pad is less than a width in the first direction of the first lower chip.
